(19) United States
(12) Patent Application Publication
(10) Pub. No.: US 2025/0151198 A1
(43) Pub. Date: May 8, 2025

(54) POWER METHOD FOR HIGHER CURRENT ASIC POWER DELIVERY

(71) Applicant: Cisco Technology, Inc., San Jose, CA (US)

(72) Inventors: Joel Richard Goergen, Soulsbyville, CA (US); Elizabeth Kochuparambil, Morgan Hill, CA (US); Scott Hinaga, Palo Alto, CA (US); Kameron Rose Hurst, Sonora, CA (US); Mike Sapozhnikov, San Jose, CA (US); Shobhana Punjabi, San Jose, CA (US); David Nozadze, San Jose, CA (US); Marco Croci, Carate Brianza MB (IT)

(21) Appl. No.: 18/434,943

(22) Filed: Feb. 7, 2024

Related U.S. Application Data
(60) Provisional application No. 63/596,989, filed on Nov. 8, 2023.

(51) Int. Cl. H05K 1/14; H05K 1/02; H05K 1/18; H05K 3/32

(52) U.S. Cl. CPC H05K 1/142; H05K 1/0203; H05K 1/18; H05K 3/321; H05K 2201/09345; H05K 2203/1131

(57) ABSTRACT

Techniques to move high current power distribution layers for integrated circuit core power and serializer-deserializer (SERDES) power into a center area of the integrated circuit footprint. This provides a more reliable and higher current distribution into the center of a large integrated circuit footprint, without causing disruption of high speed signal routing or increased signal integrity burden to the high speed signals. Arrangements and methods for routing out the core power area of a main printed circuit board under an integrated circuit and replacing it with a custom power printed circuit board (power plug) that is attached by a metalized paste sintering process. This provides a more reliable and higher current distribution into the center of a large integrated circuit or other high-power component, without causing disruption of high speed signal routing.

### PRIORITY CLAIM

This application claims priority to U.S. Provisional Application No. 63/596,989, filed Nov. 8, 2023, the entirety of which is incorporated herein by reference.

### TECHNICAL FIELD

The present disclosure relates to networking equipment.

### BACKGROUND

Transporting power into the center of an application specific integrated circuit (ASIC) for ASIC core power and ASIC serializer-de-serializer (SERDES) power at levels beyond 1000 amps can be very burdensome on layer count, power plane resistance, and high speed signaling. A substantial portion of the ASIC circuit board layers would be used for power. These additional layers are a significant cost adder to the printed circuit board.

### BRIEF DESCRIPTION OF THE DRAWINGS

FIG. 1 illustrates a top view of an conventional printed circuit board arrangement for an ASIC, and depicting the challenges associated with getting power into the ASIC for core power and series power.

FIG. 2A illustrates a top view of a printed circuit board arrangement in which the core power and SERDES power ball grid array (BGA) fields are removed from the main printed circuit board in the center of the ASIC footprint in order to transport power to the ASIC from below by a power block printed circuit board, according to an example embodiment.

FIG. 2B is an exploded side view showing a printed circuit board arrangement in which the main printed circuit board has an open section into which a power block printed circuit board is to be inserted to provide core power to an ASIC mounted on the main printed circuit board over the open section, according to an example embodiment.

FIG. 2C is side view of the printed circuit board arrangement of FIG. 2B, and showing the power block printed circuit board inserted and secure to the main printed circuit board, according to an example embodiment.

FIGS. 3A and 3B are perspective views of power block printed circuit boards that are useful in the printed circuit board arrangement shown in FIGS. 2A-2C, according to an example embodiment.

FIG. 4A is a perspective view of a power block printed circuit board having a saw-tooth side plane configuration that provides additional side plane area, according to an example embodiment.

FIG. 4B illustrates another side plane configuration of a power block printed circuit board as a variation to side plane configuration shown in FIG. 4B, according to an example embodiment.

FIG. 4C illustrates an exploded perspective view of a power block printed circuit board and a main printed circuit board having an open section sized and shaped to accommodate the shape of the power block printed circuit board, according to an example embodiment.

FIG. 5A is a side view of a printed circuit board arrangement having multiple power block printed circuit boards installed into an open section of the main printed circuit board and held in place by a pressure plate, according to an example embodiment.

FIG. 5B is a top view of the printed circuit board arrangement depicted in FIG. 5A, and showing the multiple power block printed circuit boards, according to an example embodiment.

FIGS. 6A and 6B illustrate side views showing configurations for routing power into the open section of the main printed circuit board from point of loads (POLs) that may be mounted on the main printed circuit board or on the power block printed circuit board, according to an example embodiment.

FIG. 7 illustrates an exploded view of an printed circuit board arrangement having a power block printed circuit board adapted for use with a cold plate assembly, according to an example embodiment.

FIG. 8 illustrates a perspective view of a cold plate that may be used in the arrangement of FIG. 7, according to an example embodiment.

FIGS. 9A illustrates a side view of a printed circuit board arrangement having a power block printed circuit board that is inserted in an open section of the main printed circuit board and also in an open section of a substrate of an integrated circuit, according to an example embodiment.

FIG. 9B illustrates a printed circuit board arrangement in which a main printed circuit board does not have an open section and a power block printed circuit board is inserted in an open section of a substrate of an integrated circuit, according to an example embodiment.

FIG. 10A illustrates a flow chart for a method of assembling a printed circuit board arrangement, according to one example embodiment.

FIG. 10B illustrates a flow chart for a method of assembling a printed circuit board arrangement, according to another example embodiment.

### DETAILED DESCRIPTION

### Overview

Presented herein are techniques to move high current power distribution layers for integrated circuit core power and serializer-deserializer (SERDES) power into a center area of the integrated circuit footprint. This provides a more reliable and higher current distribution into the center of a large integrated circuit footprint, without causing disruption of high speed signal routing or increased signal integrity burden to the high speed signals.

Briefly, according to one aspect, an apparatus is provided that includes a main printed circuit board and a power block printed circuit board. The main printed circuit board has a first (top) side and a second (bottom) side opposite the first side. The main printed circuit board has an open section over which an integrated circuit is configured to attach to the first side of the main printed circuit. The power block printed circuit board is sized and shaped to fit into the open section of the main printed circuit board. The power block printed circuit board has a first side that is configured to electrically connect to the integrated circuit to provide power to the integrated circuit.

According to another aspect, a method is provided. The method includes providing a main printed circuit board having a top and a bottom, the main printed circuit board having an open section that extends between the top and bottom; mounting an integrated circuit to a top of the main printed circuit board over the open section so that at least a portion of the bottom of the integrated circuit is exposed over the open section; and inserting a power block printed circuit board into the open section of the main printed circuit board from below so that a top of the power block printed circuit board makes electrical contact to the bottom of the integrated circuit.

### Example Embodiments

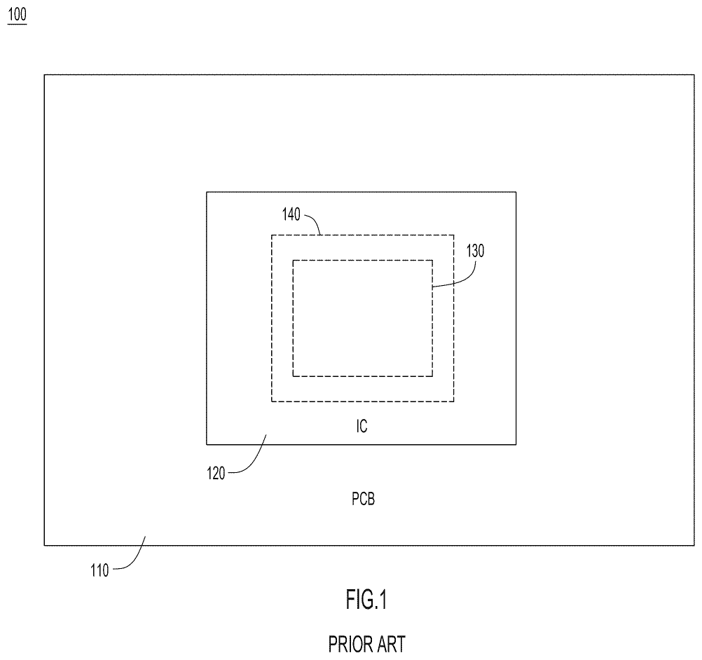

FIG. 1 illustrates a top view of a conventional circuit board arrangement 100 in which an integrated circuit is mounted. This figure depicts the challenges associated with getting power into the integrated circuit (IC) 110 for core power and SERDES power. The arrangement 100 includes a printed circuit board (PCB) 110 and an IC 120 that is mounted onto the PCB 110. The PCB 110 can have numerous layers, such as 50 layers or more, depending on the complexity of the particular application, power requirements of the integrated circuit, and surrounding components mounted on the PCB 110. This may be a common arrangement for ASIC deployments in a networking apparatus (router, etc.), for example.

In a most central area of the IC 120, shown by dotted box designating a core power area 130, is where “core” power needs to be provided for the IC core functionality. For example, the core power area 130 may need 500 amps (A) or more of power. Between the core power area 130 and another area 140 outside of the core area 130, there may be another area that needs a substantially amount of current, such as 1200 A, for example, such as for SERDES functions.

Then, there are other functions of the IC 120 outside the area 140 that need power as well as electrical connections for high-speed data, for example.

In certain applications where the PCB 110 has 50 layers (also called planes), as much as one-third of the layers may be dedicated to routing signal traces for receive signaling, the middle one-third of the layers may be dedicated for transmit signal traces and the remaining/bottom one-third of the layers may be dedicated to signal traces for power. Moreover, power to the areas 130 and 140 of the IC 120 is deployed on the outer areas of the PCB 110 and brought in from the sides of the IC 120 toward the center of the IC 120 through the numerous layers of the PCB 110 that also needs to provide traces for all the associated signal/data handled by the IC. Thus, such a PCB can be very complicated to design and expensive to build.

Presented herein are configurations and techniques to move high current power layers for core power for an integrated circuit and SERDES power into a center area of the integrated IC footprint, bringing the power in from below to as many parts of the IC and surrounding PCB functions. Briefly, presented herein is a PCB apparatus or arrangements that include a main PCB having a first (top) side and a second (bottom) side opposite the first side. The main printed circuit board having an open section that may be created by routing or otherwise removing PCB material in a volume that extends between the first side and the second side. An integrated circuit is provided that is configured to attach to the first side of the main PCB over the open section of the main printed circuit board. A power block PCB is provided that is sized and shaped to fit into the open section of the main PCB. The power block PCB has a first (top) side that is configured to electrically connect to bottom of the integrated circuit to provide power to the integrated circuit. More specifically, the arrangement of electrical connection features (e.g., pin field or ball grid array) on the first side of the power block PCB is in a pattern that is configured to mate with electrical connection features on the bottom of the integrated circuit. No changes need to be made to the design of the integrated circuit to operate in this PCB arrangement. The integrated circuit is completely agnostic to receiving power from the power block PCB rather than from the main PCB.

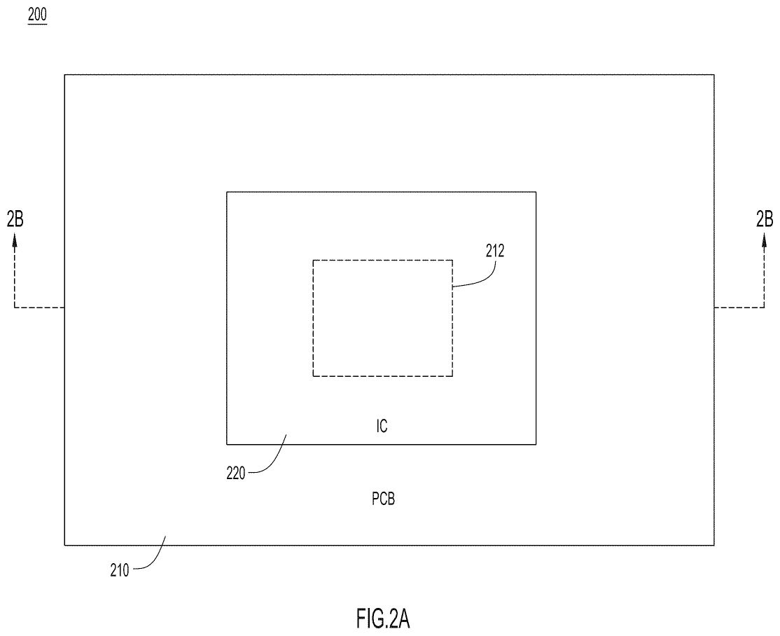

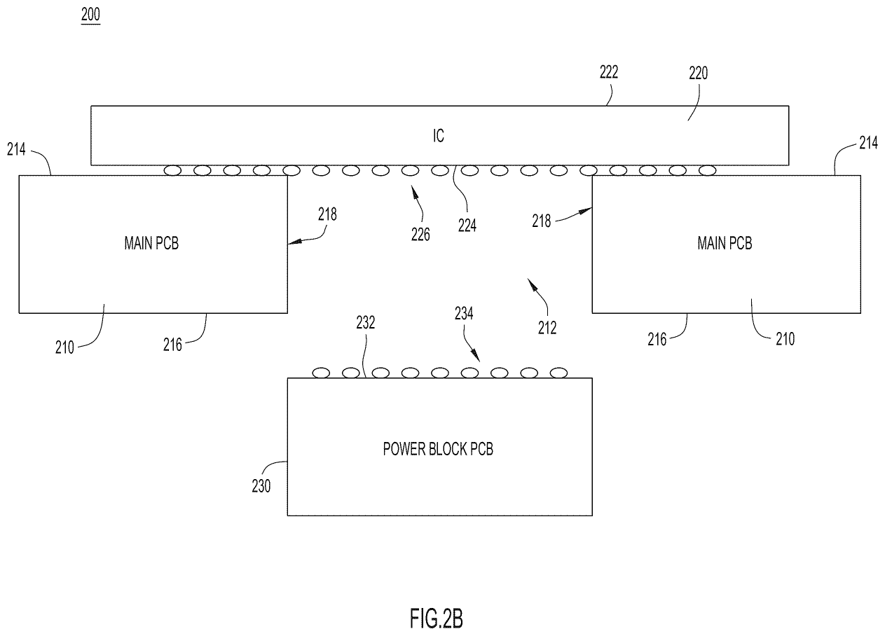

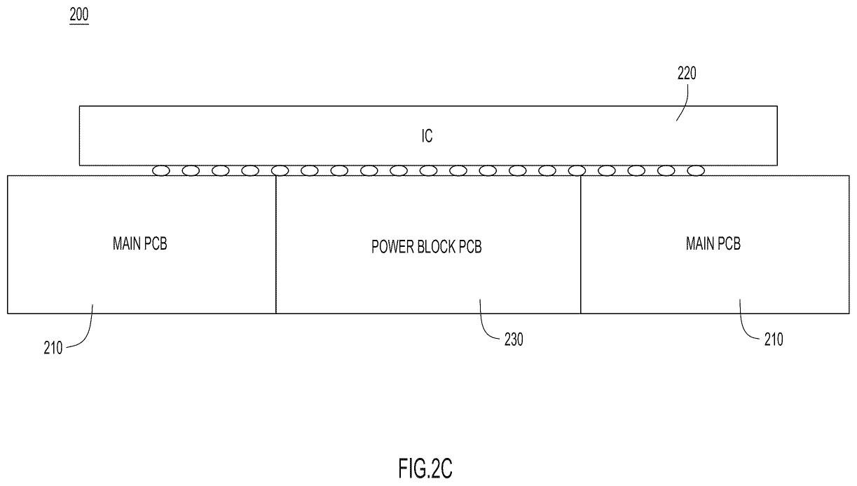

Reference is now made to FIGS. 2A-2C for a description of a circuit board arrangement 200 according to an example embodiment. FIG. 2A illustrates a top view of the circuit board arrangement 200. The circuit board arrangement 200 includes a main PCB 210 and an IC 220 that mounts to a top of the PCB 210. The PCB 210 is referred to herein as the “main” PCB from reasons that will become apparent below.

The cross-sectional view of FIG. 2B shows that a portion of a center area of the main PCB 210 that has been removed beneath a central part of the footprint of the IC 220. This center area is where, in the arrangement of FIG. 1, the main PCB 210 would have had the routing of traces for core power and SERDES power to the IC 220. All of this routing is re-worked. As shown in FIG. 2B, the main PCB 210 has a first (top) side 214 and a second (bottom) side 216 that is opposite the first side 214. The center area of the main PCB 210 is removed to provide a cut-out for an open (volume) section 212 at a location corresponding to a central area of the footprint of the IC 220. Thus, the IC 220 is configured to attach to the first side 214 of the main PCB 210 over the open section 212. The open section 212 extends through the entire volume or thickness of the main PCB 210. The IC 220 has a first (top) side 222 and a second (bottom) side 224. The IC 220 includes a pin field or ball grid array (BGA) 226 on the second side 224.

With the central area removed from the main PCB 210 to create the open section 212, the PCB 210 may be plated. The core power is not provided by the main PCB 210, but the SERDES power vias and BGA pads are still in place. The SERDES power is accessible for connection laterally from inside the central area as shown at 218 in FIG. 2B.

A power block PCB 230 (also called a power plug PCB or power plug) is provided that is sized and shaped to fit within the open section 212 of the main PCB 210. The power block PCB 230 may be fabricated of the same types of materials, using the same types of technologies as used to fabricate the main PCB 210, to create conductive traces and layers of electrically insulating material.

The power block PCB 230 has a first (top) side 232 that includes a pin field or ball grid array 234 that is in an pattern appropriate and configured to electrically connect to the ball grid array or pin field 226 on the IC 220. In one example, the pin field or ball grid array 234 on the first side 232 of the power block PCB 230 is in a pattern that is configured to mate with the pin field or ball grid array 226 on the IC 220 to supply core power to the IC 220.

FIG. 2C shows the power block PCB 230 fully inserted into the open section 212 and making electrical contact to the IC 220 to provide power to core area of the IC 220 from below, as well as to provide power to the main PCB 210, in a lateral direction into layers of the main PCB 210. In this arrangement, power to the core/central area of the IC 220 is brought in from below the IC 220 by the power block PCB 230, without having to traverse laterally through the layers of the main PCB 210 to the IC 220.

As is known in the art, there are specifications set for how flat the entire PCB needs to be, in order for all the pins of the IC 220 to solder on evenly, without breaking, etc. When the power block PCB 230 is inserted into the main PCB 210, mechanisms are employed to ensure that the top of the power block PCB 230 is co-planar with the top of the main PCB 210. Examples of mechanism to adhere/affix the power block PCB 230 to the main PCB 210 include metallization/sintering using a conductive paste, as well as spring-loaded, clips, etc., as described further below. The design of the IC 220 is completely independent of the power block PCB arrangement and needs no design alterations. When the power block PCB 230 is inserted into the main PCB 210, and secured to the main PCB 210 using any of the techniques described herein, the power block PCB 210 replaces the routed out part of the main PCB 210.

The power block PCB 230 may provide power, from beneath the IC 220, to the “heavier” or core power needs of the IC 220 (e.g., 500-800 A). In addition, the power block PCB 230 may provide power laterally into the main PCB 210 for other power needs (e.g., 250-400 A). This can be particularly advantageous to supply power to application specific ICs (ASICs) that perform substantial power heavy signal processing functions, such as for electrical or optical signal transmission and reception, video signal processing, etc.

By moving a large amount of the power delivery functions to the power block PCB 230 that is arranged at a central area of the IC, the number of layers of the main PCB 210 can be reduced/minimized. These techniques fundamentally change how to transport power into an IC.

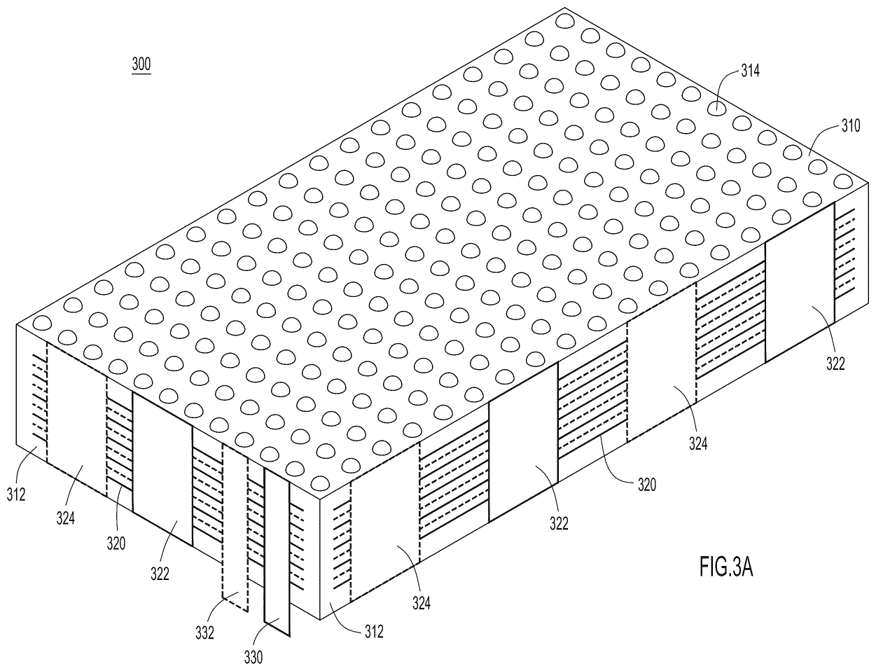

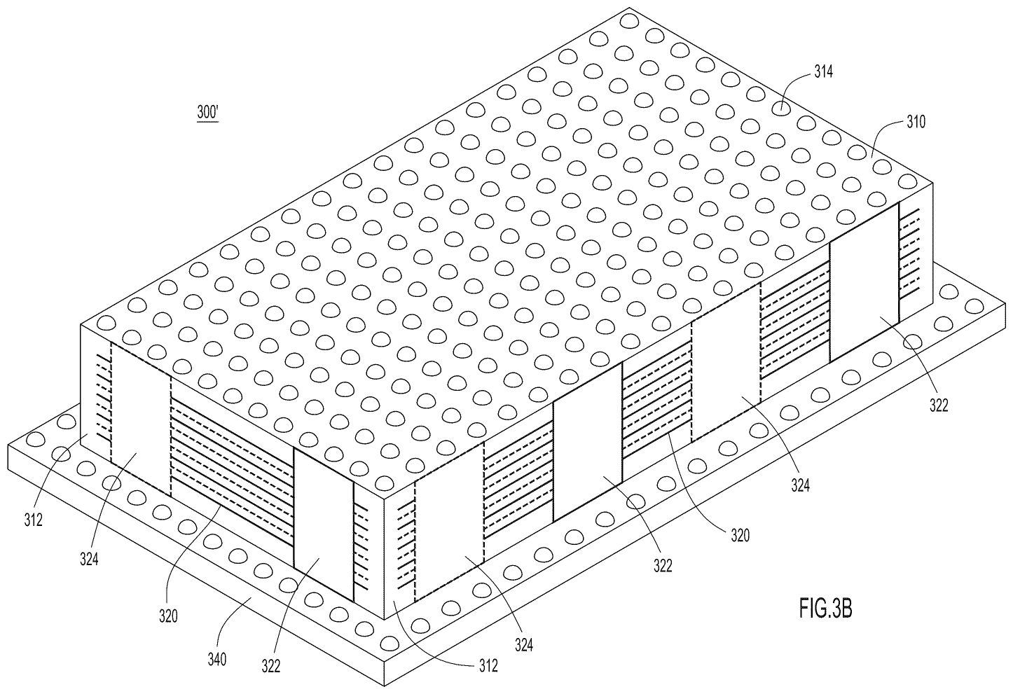

Reference is now made to FIG. 3A, which shows a perspective view of a power block PCB 300, according to example embodiments. The power block PCB 300 includes a top side 310, lateral sides 312 as well as a bottom side (not visible in FIG. 3A). The dimensions of the power block PCB 300 may vary, but in one example it may be 35 mm wide×35 mm deep. The top side 310 has a ball grid array (BGA) pad 314 that is configured to connect to the bottom of the IC through a standard BGA reflow process. The BGA pad 314 may couple core power to the IC. The power block PCB 300 may be made of the same materials as the main PCB.

The power block PCB 300 may be made from several layers 320 (e.g., of 3 oz copper) for very high current delivery to the BGA pad 314 with minimal loss. The power block PCB 300 may include vertical conductive stripe traces 322 and 324 on the sides 312 for multiple different/independent pairs of power and ground rails (of different power levels), respectively, that connect laterally into conductive traces in the main PCB.

The power block PCB 300 may include power studs 330 and 332 for receiving input power to be delivered by the power block PCB 300 to the IC and main PCB. Several bus bar or cabling methods may be used to deliver current to the power block PCB 300 for IC core power and SERDES power, as well as other power needs. A bus bar integrated point of load (POL) may be employed. Connection of the bus bars or wires may be made, from beneath the power block PCB 300, by solder attach or by stud mount attach to the power studs 330 and 332. There may be several power studs on the power block PCB 300, and only one pair is shown in FIG. 3A for simplicity.

FIG. 3B illustrates a power block PCB 300′ that is similar to the power block PCB 300 shown in FIG. 3A, but further including a metal grounding ring 340 on the bottom. A silver filled conductive paste may be applied around a top surface of the grounding ring 340 that serves as a tab to secure the power block PCB 300′ to the main PCB. Alignment and set pins may be provided on the top side 310 for silver reflow process to the bottom of the IC. If a metalized post-sinter cure process is used to secure the power block PCB to the main PCB, the grounding ring 340 may not be necessary.

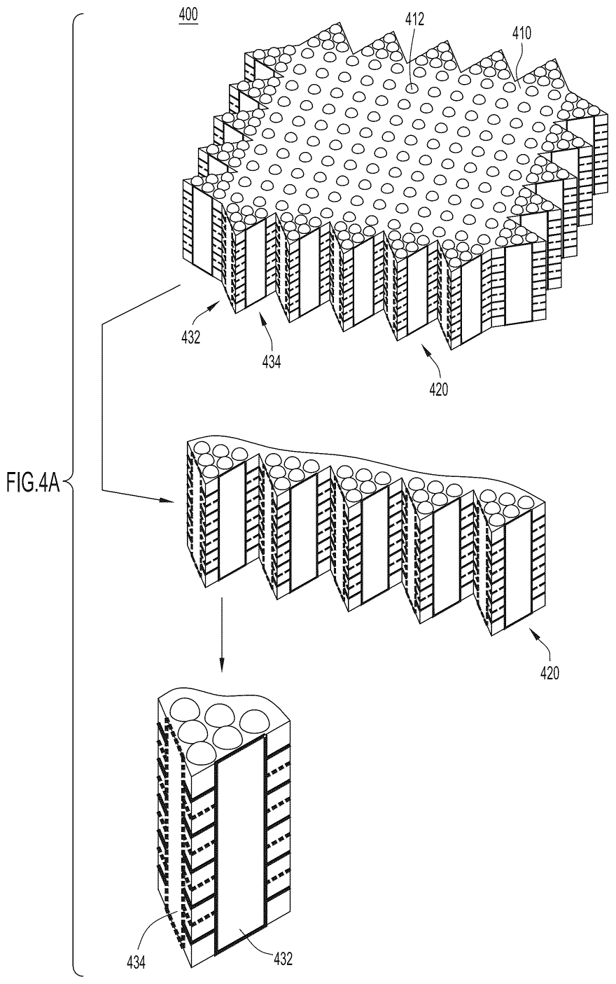

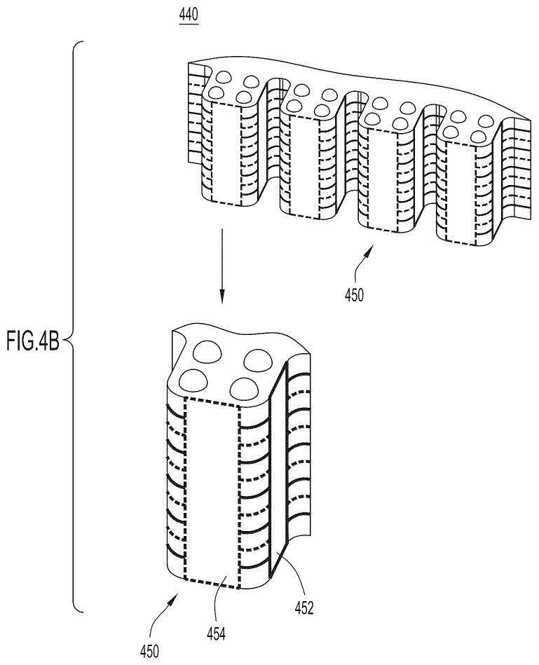

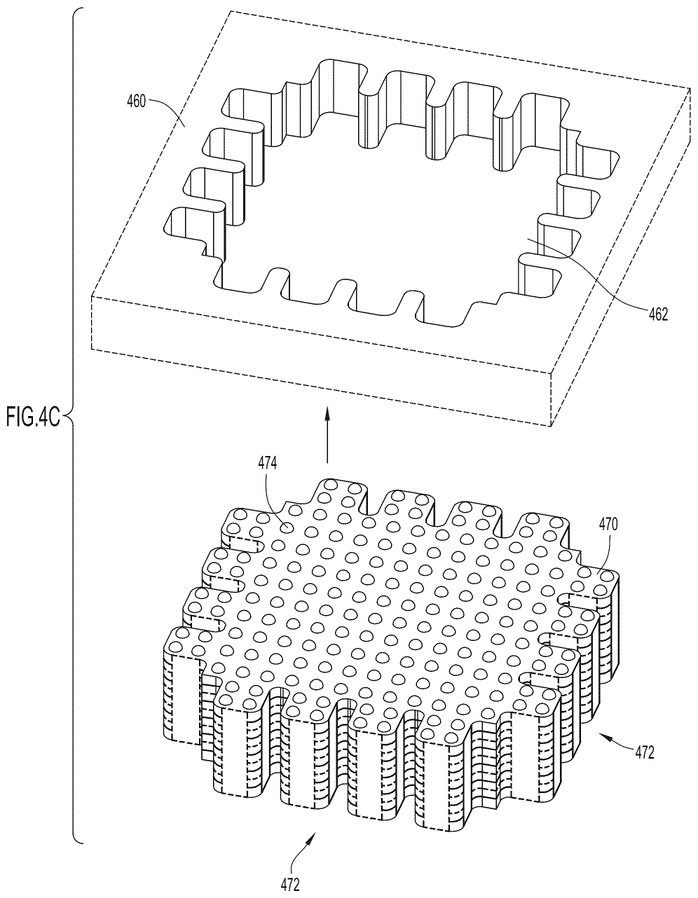

Reference is now made to FIGS. 4A and 4B for descriptions of further example variations of power block PCBs. FIG. 4A illustrates a power block PCB 400 having a top side 410 with a BGA pad 412, and sides that have a saw-tooth side plane/rail configuration 420. In this arrangement, the saw-tooth configuration can increase the side plane area by up to 50%. The area increase has a direct impact to conductivity. A given tooth may be alternating ground plane and power plane 432 and 434, respectively, or it can be the same plane (ground or power) for each tooth. This configuration of ASIC power delivery increases conductivity in the connection between the power block and the main board that utilizes a metalizing/sintering process (where the conductivity may be reduced because of the metalizing/sintering process). The BGA pad 412 extends onto the tops of the teeth, as shown in FIG. 4A.

The saw-tooth configuration of FIG. 4A may be suitable for some applications. In analyzing the mechanical routing method used to cut the shape from the main PCB under the IC package, and taking into account the BGA SERDES power and ground BGA layout, a flattened or squared tooth structure, shown in FIG. 4B may be useful. FIG. 4B shows one side 440 of a power block PCB comprises a tooth pattern having teeth 450 having a flattened/square structure. Teach tooth may have a power side rail 452 and a ground side rail 454 on adjacent (but perpendicular) sides of the tooth. Each of the teeth 450 has three sides or faces, and the third side or face (not visible in FIG. 4B) may also be used for a power side rail or ground side rail. This flattened tooth structure may have improved mechanical/routing features, electrical characteristics, and may be more accommodating to the ASIC package.

Reference is now made to FIG. 4C. FIG. 4C illustrates a PCB assembly that includes a main PCB 460 having an open section 462 that is sized and shaped to complement/match the size and shape of a power block PCB 470, and in particular of the tooth pattern on the periphery of the power block PCB 470. The power block PCB 470 has multiple power and ground layers, using the flattened tooth structure for the side planes, shown at reference numeral 472, similar to that shown in FIG. 4B. The power block PCB 470 fits into the cut-out section or open section 462 of the main PCB 460. The power block PCB 470 further includes a pin field of BGA pad 474 on the top side thereof. Metallization may be employed along the sides of the power block PCB 470 where it interfaces with the main PCB 460.

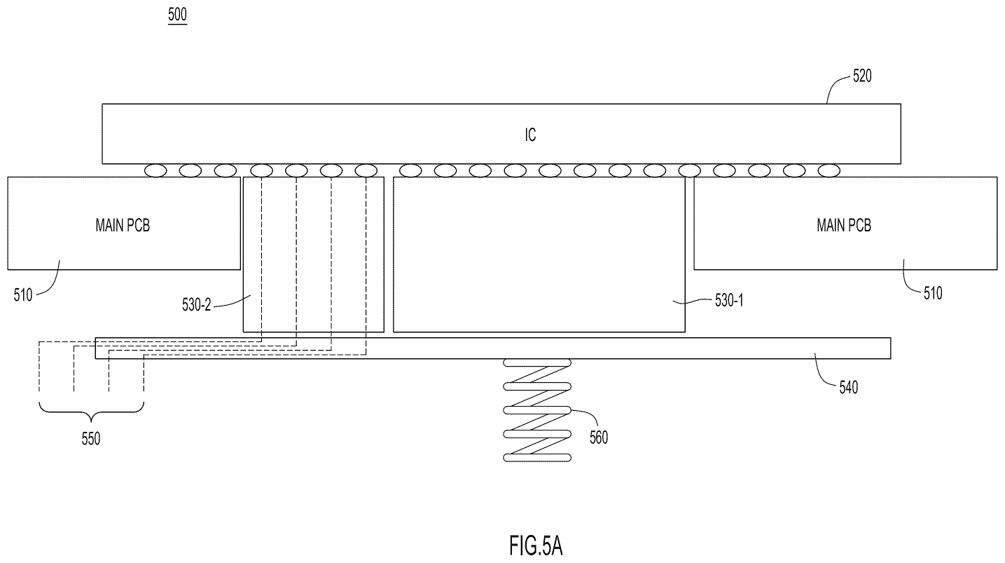

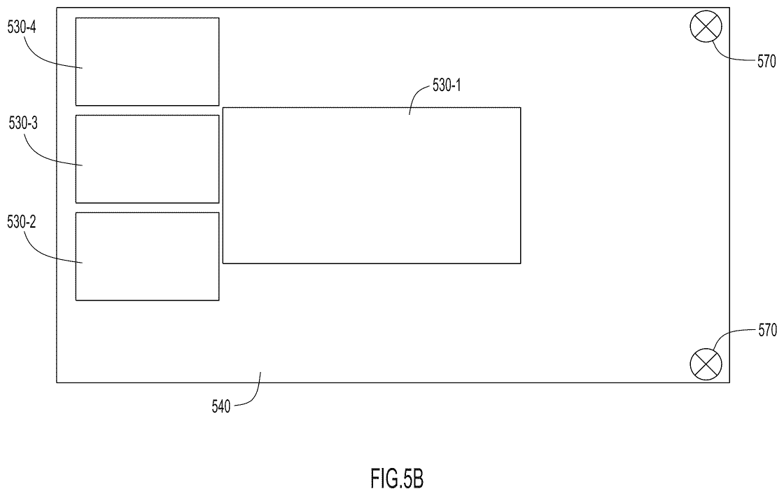

Reference is now made to FIGS. 5A and 5B. These figures show a PCB arrangement 500 that features a plurality of power block PCBs and a pressure plate/frame. FIG. 5B is a top view of the pressure plate with the multiple power block PCBs. The PCB arrangement 500 includes a main PCB 510, an IC 520 mounted on top of the main PCB 510, a plurality of power PCB blocks 530-1 to 530-4 (only two of which are visible in FIG. 5A) that, collectively, fit into and fill an open section of the main PCB 510, and a pressure plate 540. The power block PCB 530-1 may be dedicated to providing core power to the IC 520. The other PCB blocks 530-2, 530-3 and 530-4 may be used for fly over cable routing shown at 550, such as for fly-over high speed cables, via the pressure plate 540. Each of the plurality of power block PCBs 530-1-530-4 is configured to electrically connect to the IC 520 to provide power to the IC 520.

A spring mechanism may be used to bias a pressure plate 540 upwards against the main PCB 510 to ensure sufficient is applied to maintain BGA contact between the power block PCBs and the IC 520. In this regard, FIG. 5A shows a spring 560. The pressure plate 540 may also have spring-loaded screws 570 in various locations to hold the pressure plate 540 against the main PCB 510.

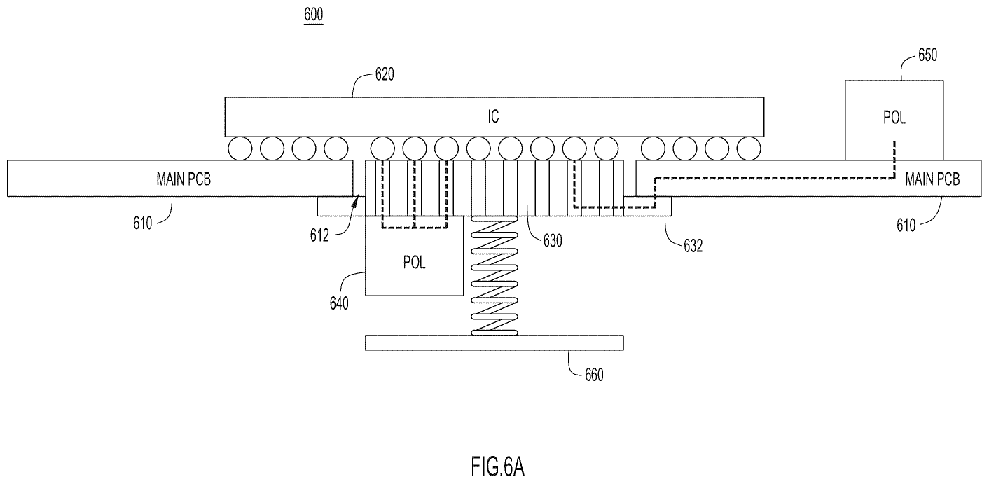

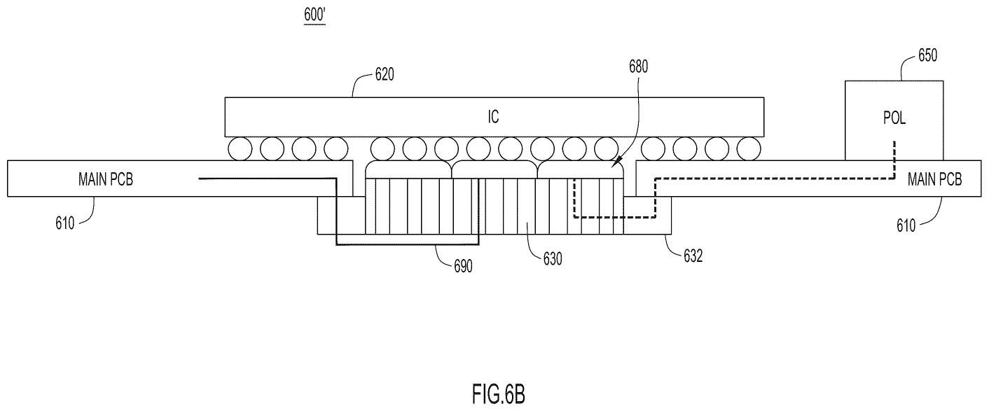

FIGS. 6A and 6B illustrate configurations for routing power into the open area of the main PCB from point of loads (POLs).

FIG. 6A shows a side view of a PCB arrangement 600 that includes a main PCB 610, an IC 620 mounted on the main PCB 610 and a power block PCB 630 inserted into an open section 612 of the main PCB 610. A POL 640 may be deployed on the bottom side of the power block PCB 630, coupled (such as by way of a bus bar interconnection) to the power block PCB 630 for delivery to the IC 620. In another example, a POL source 650 may be deployed on the main PCB 610 and coupled to and through the ring of the main PCB 610 around the power block PCB 630, through a tab 632 on the power block PCB 630 and then up to the IC 620. The POL 640 may be particularly useful for higher voltage, e.g., 56 VDC. Similar to FIG. 5A, FIG. 6A shows a spring 660 to indicate that a spring compression method may be used to provide compression for electrical connections between the IC 620 and the pin field of the power block PCB 630.

FIG. 6A also shows, at reference numeral 670, that a slot and spring tab may be employed at the physical interface between the top side of the power block PCB 630 and the bottom of the IC 620. The spring compression and conductivity points could be small spring pins pressure loaded to contact with the IC package after the IC is soldered to the main board. A spring tab may be employed that contacts multiple power or ground balls/pins on the IC to ground or core voltage power rail.

FIG. 6B shows a PCB arrangement 600′ that is similar to PCB arrangement 600 shown in FIG. 6A, but featuring multiple copper spring tabs 680 connecting multiple rail voltages to POL(s), as shown at 690. Since the tabs are spring loaded, there is no need for a spring mechanism pushing the power block into the ASIC.

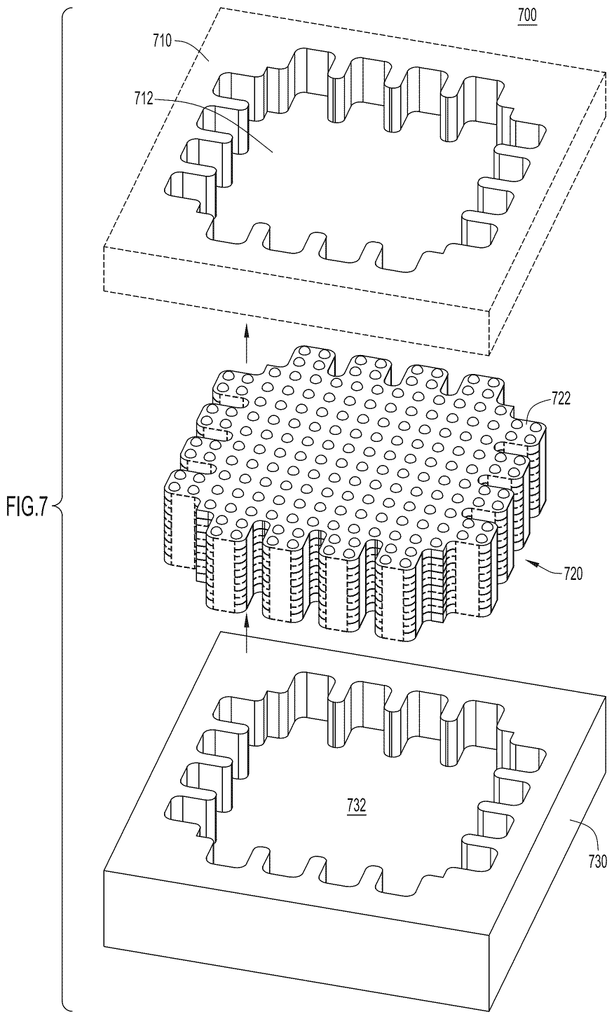

FIG. 7 illustrates an exploded view of an PCB arrangement 700 having a power block PCB adapted for deployment with a cold plate. The PCB arrangement 700 includes a main PCB 710 having a cut-out for an open section 712 that is sized and shaped to accommodate a power block PCB 720. A cold plate 730 is provided that has a well 732 that is sized and shaped to allow the cold plate 730 to slide over a bottom exposed portion/thickness of the power block PCB 720 that is not surrounded by the main PCB 710 when the power block PCB 720 is inserted and secured to the main PCB 710. The power block PCB 720 has a thickness that is greater than a thickness of the main PCB 710 so that the top side 722 of the power block PCB 720 is co-planar with the top side of the main PCB 710, and the bottom side (not shown in FIG. 7) of the power block PCB 720 extends beyond the bottom of the main PCB 710. This allows the cold plate 730 to fit over a bottom portion of the power block PCB 720 that extends beyond the bottom of the main PCB 710. The cold plate 730 dissipates heat from the power block PCB 720. Power may come in from the sides to the power block PCB 720 via a cabling method, rather than just to power studs that are shown in FIG. 3A or some other connection method from below. The cold plate 730 is configured to dissipate heat from power block PCB 720. It should be understood that FIG. 7 illustrates the arrangement from the bottom side of the PCB but it is also envisioned that the arrangement may be down from the top side of the main PCB 710.

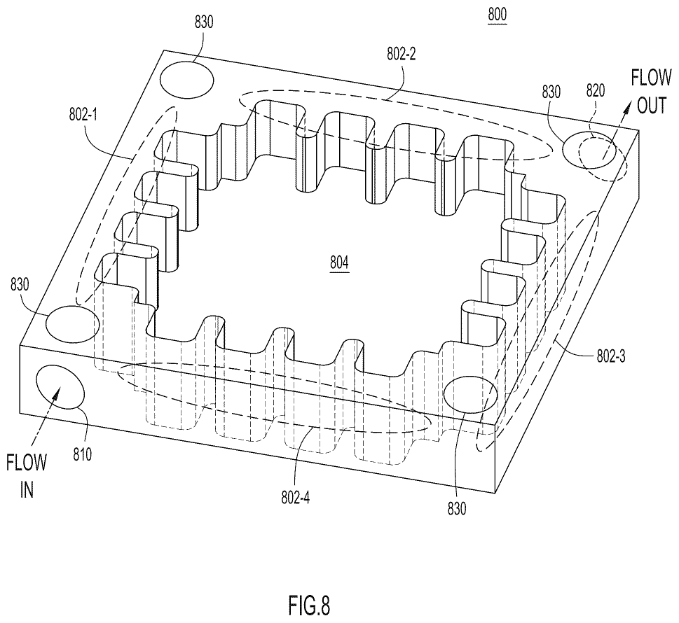

FIG. 8 illustrates in more detail a cold plate 800, such as the cold plate used in the PCB arrangement of FIG. 7. The cold plate 800 may have multiple (e.g., four) different flow rate cooling zones 802-1, 802-2, 802-3 and 802-4 (through which a heat exchange fluid is directed) to allow parts of the power block PCB cool at different rates. A routed-out or cut-away section 804 is shown to accommodate a power block PCB. Cooling fluid enters at the “flow in” point 810 and departs the cold plate at the “flow out” point 820. The are several “touch points” 830 shown in FIG. 8. These touch points 830 are areas of the cold plate 800 that could directly contact an IC from below the power block PCB to assist in cooling the IC.

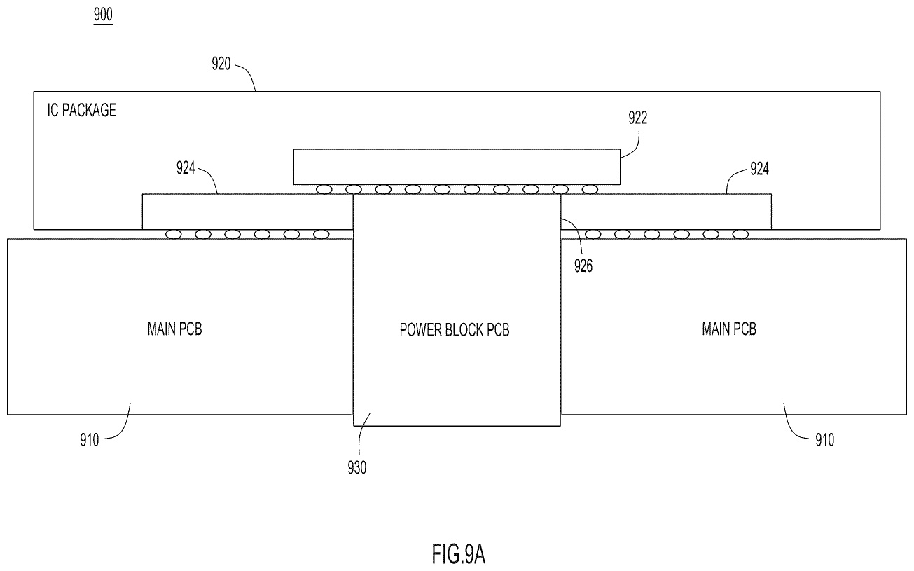

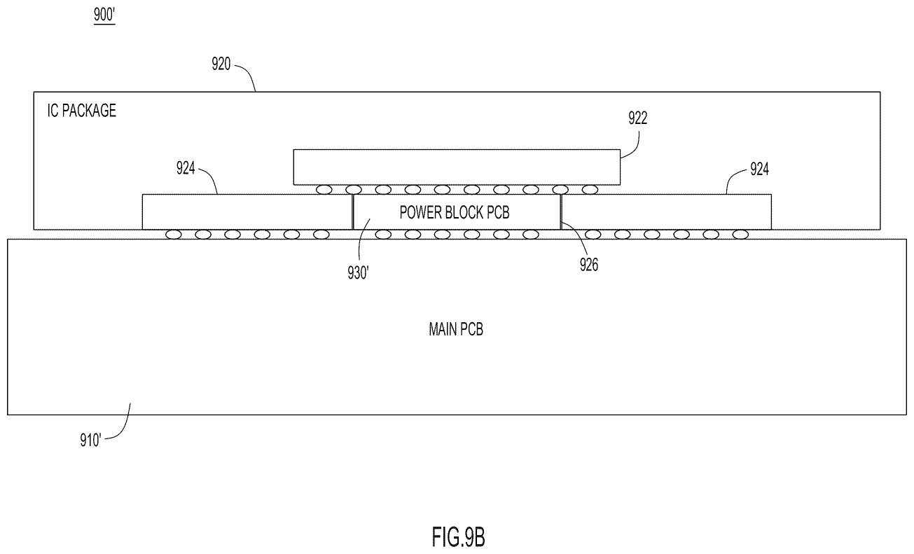

Reference is now made to FIGS. 9A and 9B. These figures show extensions of the concepts of a power block PCB into an IC package. FIG. 9A shows a PCB arrangement 900 including a main PCB 910, an IC package 920 that includes a die 922 mounted on a substrate 924, and a power block PCB 930. The main PCB 910 includes an open section to accommodate the power block PCB 930. In addition, the substrate 924 includes an open section 926 to accommodate the power block PCB 930. The open section 926 is aligned with at least part of the open section of the main PCB 910. Thus, the power block PCB 930 extends through the main PCB 910 and through the open section 926 of the substrate 924 to connect to the die 922 of the IC package 920, enabling coupling of power directly to the die 922 from below, and laterally into the substrate 924. Thus, the PCB arrangement 900, the power block PCB 930 extends through an open section of the main PCB 910 as well as through an open section of the substrate 924 of the IC package to electrically connect with the die 922. The power block PCB 930 also can delivery power laterally into the main PCB 910, as described above in connection with several embodiments.

FIG. 9B illustrates a PCB arrangement 900′, which is a variation of the PCB arrangement 900. In PCB arrangement 900′, the main PCB 910′ does not have an open section and thus the power block PCB 930′ does not extend through the main PCB 910′. Instead, the power block PCB 930′ extends between the top of the main PCB 910 and through open section 926 of the substrate 924 to electrically connect to the die 922. Thus, in this variation, the power block PCB 930′ serves to connect power obtained from the main PCB 910 to the die 922 of the IC package 920.

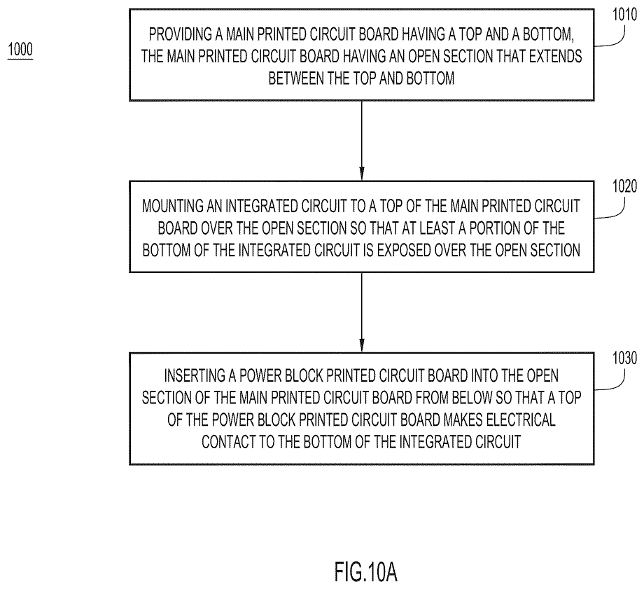

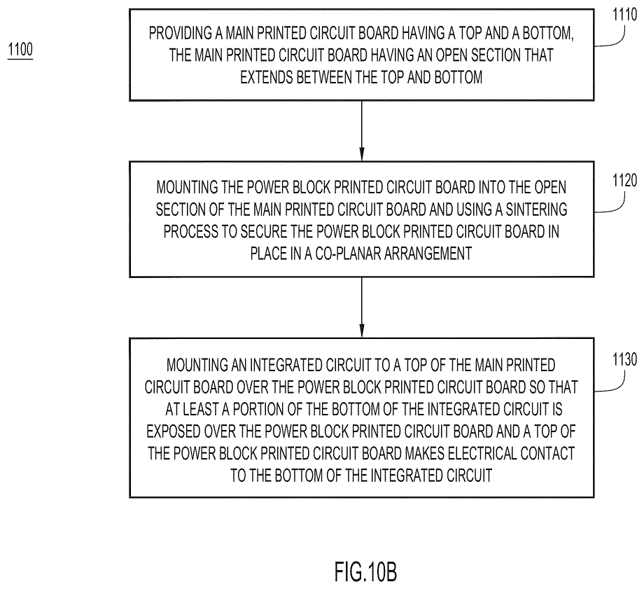

FIG. 10A illustrates a flow chart depicting a method 1000 for assembling a printed circuit board arrangement, according to one example embodiment. The method 1000 includes, at step 1010, providing a main printed circuit board having a top and a bottom. The main printed circuit board has an open section that extends between the top and bottom. At step 1020, the method 1000 includes mounting an integrated circuit to a top of the main printed circuit board over the open section so that at least a portion of the bottom of the integrated circuit is exposed over the open section. At step 1030, the method 1000 includes inserting a power block printed circuit board into the open section of the main printed circuit board from below so that a top of the power block printed circuit board makes electrical contact to the bottom of the integrated circuit.

As explained above, the power block printed circuit board may be secured to the main printed circuit board using a conductive paste and sintering process, and/or one engaging one or more spring clips.

FIG. 10B illustrates a flow chart depicting a method 1100 for assembling a printed circuit board arrangement, according to another example embodiment. The method 1100 includes at step 1110, providing a main printed circuit board, and cutting out/routing out or otherwise removing a section of the main printed circuit board to be replaced, to create an open section that extends between the top and bottom of the main printed circuit board.

At step 1120, the method 1100 includes inserting and mounting the power block printed circuit board into the open section of the main printed circuit board and using a sintering process to secure the power block printed circuit board in place, and in some arrangements, additionally using a fixture mechanism (many of which are described above) to maintain a co-planar arrangement between the top of the main printed circuit board and the top of the power block printed circuit board.

At step 1130, the method 1100 includes mounting an integrated circuit to a top of the main printed circuit board over the power block so that at least a portion of the bottom of the integrated circuit is exposed over the power block printed circuit board and a top of the power block printed circuit board makes electrical contact to the bottom of the integrated circuit. The integrated circuit is then secured to the main printed circuit board (and power block printed circuit board) using a reflow process and associated known methods or reflow techniques.

In summary, arrangements and methods are presented herein for routing out the core power area of a printed circuit board under an IC and replacing it with a custom power block/plug printed circuit board that is attached by a metalized paste sintering process or other techniques to the main printed circuit board. As an example, this may be used for power delivery for ASICs or other high-power ASICs or other ICs (e.g., those drawing 1 kW or more) and is advantageous over other power delivery methods heretofore known.

In some aspects, the techniques described herein relate to an apparatus including: a main printed circuit board having a first side and a second side opposite the first side, the main printed circuit board having an open section; an integrated circuit configured to attach to the first side of the main printed circuit board over the open section of the main printed circuit board; and a power block printed circuit board sized and shaped to fit into the open section of the main printed circuit board, the power block printed circuit board having a first side that is configured to electrically connect to the integrated circuit to provide power to the integrated circuit.

In some aspects, the techniques described herein relate to an apparatus, wherein the power block printed circuit board includes multiple layers between the first side and the second side, and side planes around a periphery, the side planes configured to laterally contact and electrically connect with layers in the main printed circuit board to provide power into the main printed circuit board.

In some aspects, the techniques described herein relate to an apparatus, wherein the side planes around the periphery of the power block printed circuit board include a tooth pattern such that each tooth of the tooth pattern has at least two faces that supports power or ground side rails.

In some aspects, the techniques described herein relate to an apparatus, wherein each tooth of the tooth pattern is flattened to create three faces, each of which supports power or ground side rails.

In some aspects, the techniques described herein relate to an apparatus, wherein the open section of the main printed circuit board is sized and shaped to accommodate the tooth pattern on the periphery of the power block printed circuit board.

In some aspects, the techniques described herein relate to an apparatus, wherein the power block printed circuit board is secured to the main printed circuit board by sintering of a metallization paste.

In some aspects, the techniques described herein relate to an apparatus, further including one or more spring clips to secure the power block printed circuit board to the second side of the main printed circuit board.

In some aspects, the techniques described herein relate to an apparatus, further including: a frame that engages a second side of the power block printed circuit board; and a spring mechanism configured to bias the frame to apply pressure between the power block printed circuit board and the integrated circuit.

In some aspects, the techniques described herein relate to an apparatus, wherein the first side of the power block printed circuit board includes a pin field or ball grid array that is configured to electrically connect to a pin field or ball grid array of the integrated circuit.

In some aspects, the techniques described herein relate to an apparatus, wherein the pin field or ball grid array on the first side of the power block printed circuit board is in a pattern that is configured to mate with the pin field or ball grid array on the integrated circuit to supply core power to the integrated circuit.

In some aspects, the techniques described herein relate to an apparatus, wherein the power block printed circuit board has a thickness that is greater than a thickness of the main printed circuit board and is secured to the main printed circuit board in the open section so that the first side of the power block printed circuit board is co-planar with the first side of the main printed circuit board, and the second side of the power block printed circuit board extends beyond the second side of the main printed circuit board.

In some aspects, the techniques described herein relate to an apparatus, further including a cold plate having an open section configured to fit over a portion of the power block printed circuit board that extends beyond the second side of the main printed circuit board, wherein the cold plate is configured to dissipate heat from the power block printed circuit board.

In some aspects, the techniques described herein relate to an apparatus, wherein the cold plate has multiple cooling zones through which a heat exchange fluid is directed.

In some aspects, the techniques described herein relate to an apparatus, further including a plurality of power block printed circuit boards that collectively fit into and fill the open section of the main printed circuit board, each of the plurality of power block printed circuit boards having a first side that is configured to electrically connect to the integrated circuit to provide power to the integrated circuit.

In some aspects, the techniques described herein relate to an apparatus, wherein the integrated circuit includes a die and a substrate, wherein the die is mounted on the substrate, wherein the substrate has an open section that is aligned with at least part of the open section in the main printed circuit board, and the power block printed circuit board extends through the open section of the substrate so that the first side of the power block printed circuit board makes electrical contact with the die.

In some aspects, the techniques described herein relate to an apparatus including: a main printed circuit board having a top and a bottom, the main printed circuit board having an open section over which an integrated circuit is configured to attach; and a power block printed circuit board configured to fit into the open section of the main printed circuit board, the power block printed circuit board having a top that electrically connects to the integrated circuit to provide power to the integrated circuit from below.

In some aspects, the techniques described herein relate to an apparatus, wherein the power block printed circuit board includes multiple layers between the top and bottom, and side planes around a periphery, the side planes configured to laterally contact and electrically connect with layers in the main printed circuit board to provide power into the main printed circuit board.

In some aspects, the techniques described herein relate to an apparatus, wherein the side planes around the periphery of the power block printed circuit board include a tooth pattern such that each tooth of the tooth pattern has at least two faces that supports power or ground side rails, and wherein the open section of the main printed circuit board is sized and shaped to accommodate the tooth pattern on the periphery of the power block printed circuit board.

In some aspects, the techniques described herein relate to an apparatus, wherein the top of the power block printed circuit board includes a pin field or ball grid array that is configured to electrically connect to a pin field or ball grid array of the integrated circuit, wherein the pin field or ball grid array on the top of the power block printed circuit board is in a pattern that is configured to mate with the pin field or ball grid array on the integrated circuit to supply core power to the integrated circuit.

In some aspects, the techniques described herein relate to an apparatus, further including a plurality of power block printed circuit boards that collectively fit into and fill the open section of the main printed circuit board, each of the plurality of power block printed circuit boards having a top that is configured to electrically connect to the integrated circuit to provide power to the integrated circuit.

In some aspects, the techniques described herein relate to a method including: providing a main printed circuit board having a top and a bottom, the main printed circuit board having an open section that extends between the top and bottom; mounting an integrated circuit to a top of the main printed circuit board over the open section so that at least a portion of the bottom of the integrated circuit is exposed over the open section; and inserting a power block printed circuit board into the open section of the main printed circuit board from below so that a top of the power block printed circuit board makes electrical contact to the bottom of the integrated circuit.

In some aspects, the techniques described herein relate to a method, further including securing the power block printed circuit board to the main printed circuit board using a conductive paste and sintering process, and/or one engaging one or more spring clips.

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/−5%, within +/−4%, within +/−3%, within +/−2%, within +/−1%, or even closer, of the given value. Similarly, when a given feature is described as being “substantially parallel” to another feature, “generally perpendicular” to another feature, and so forth, this is intended to convey that the given feature is within +/−5%, within +/−4%, within +/−3%, within +/−2%, within +/−1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree, but may have minor deviation from exactly parallel.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function] . . . or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. An apparatus comprising:
a main printed circuit board having a first side and a second side opposite the first side, the main printed circuit board having an open section;
an integrated circuit configured to attach to the first side of the main printed circuit board over the open section of the main printed circuit board; and
a power block printed circuit board sized and shaped to fit into the open section of the main printed circuit board, the power block printed circuit board having a first side that is configured to electrically connect to the integrated circuit to provide power to the integrated circuit.

2. The apparatus of claim 1, wherein the power block printed circuit board comprises multiple layers between the first side and the second side, and side planes around a periphery, the side planes configured to laterally contact and electrically connect with layers in the main printed circuit board to provide power into the main printed circuit board.

3. The apparatus of claim 2, wherein the side planes around the periphery of the power block printed circuit board comprise a tooth pattern such that each tooth of the tooth pattern has at least two faces that supports power or ground side rails.

4. The apparatus of claim 3, wherein each tooth of the tooth pattern is flattened to create three faces, each of which supports power or ground side rails.

5. The apparatus of claim 3, wherein the open section of the main printed circuit board is sized and shaped to accommodate the tooth pattern on the periphery of the power block printed circuit board.

6. The apparatus of claim 1, wherein the power block printed circuit board is secured to the main printed circuit board by sintering of a metallization paste.

7. The apparatus of claim 1, further comprising one or more spring clips to secure the power block printed circuit board to the second side of the main printed circuit board.

8. The apparatus of claim 1, further comprising:
a frame that engages a second side of the power block printed circuit board; and
a spring mechanism configured to bias the frame to apply pressure between the power block printed circuit board and the integrated circuit.

9. The apparatus of claim 1, wherein the first side of the power block printed circuit board comprises a pin field or ball grid array that is configured to electrically connect to a pin field or ball grid array of the integrated circuit.

10. The apparatus of claim 9, wherein the pin field or ball grid array on the first side of the power block printed circuit board is in a pattern that is configured to mate with the pin field or ball grid array on the integrated circuit to supply core power to the integrated circuit.

11. The apparatus of claim 1, wherein the power block printed circuit board has a thickness that is greater than a thickness of the main printed circuit board and is secured to the main printed circuit board in the open section so that the first side of the power block printed circuit board is co-planar with the first side of the main printed circuit board, and the second side of the power block printed circuit board extends beyond the second side of the main printed circuit board.

12. The apparatus of claim 11, further comprising a cold plate having an open section configured to fit over a portion of the power block printed circuit board that extends beyond the second side of the main printed circuit board, wherein the cold plate is configured to dissipate heat from the power block printed circuit board.

13. The apparatus of claim 12, wherein the cold plate has multiple cooling zones through which a heat exchange fluid is directed.

14. The apparatus of claim 1, further comprising a plurality of power block printed circuit boards that collectively fit into and fill the open section of the main printed circuit board, each of the plurality of power block printed circuit boards having a first side that is configured to electrically connect to the integrated circuit to provide power to the integrated circuit.

15. The apparatus of claim 14, wherein the integrated circuit comprises a die and a substrate, wherein the die is mounted on the substrate, wherein the substrate has an open section that is aligned with at least part of the open section in the main printed circuit board, and the power block printed circuit board extends through the open section of the substrate so that the first side of the power block printed circuit board makes electrical contact with the die.

16. An apparatus comprising:
a main printed circuit board having a top and a bottom, the main printed circuit board having an open section over which an integrated circuit is configured to attach; and
a power block printed circuit board configured to fit into the open section of the main printed circuit board, the power block printed circuit board having a top that electrically connects to the integrated circuit to provide power to the integrated circuit from below.

17. The apparatus of claim 16, wherein the power block printed circuit board comprises multiple layers between the top and bottom, and side planes around a periphery, the side planes configured to laterally contact and electrically connect with layers in the main printed circuit board to provide power into the main printed circuit board.

18. The apparatus of claim 17, wherein the side planes around the periphery of the power block printed circuit board comprise a tooth pattern such that each tooth of the tooth pattern has at least two faces that supports power or ground side rails, and wherein the open section of the main printed circuit board is sized and shaped to accommodate the tooth pattern on the periphery of the power block printed circuit board.

19. The apparatus of claim 16, wherein the top of the power block printed circuit board comprises a pin field or ball grid array that is configured to electrically connect to a pin field or ball grid array of the integrated circuit, wherein the pin field or ball grid array on the top of the power block printed circuit board is in a pattern that is configured to mate with the pin field or ball grid array on the integrated circuit to supply core power to the integrated circuit.

20. The apparatus of claim 16, further comprising a plurality of power block printed circuit boards that collectively fit into and fill the open section of the main printed circuit board, each of the plurality of power block printed circuit boards having a top that is configured to electrically connect to the integrated circuit to provide power to the integrated circuit.

21. A method comprising:
providing a main printed circuit board having a top and a bottom, the main printed circuit board having an open section that extends between the top and bottom;
mounting an integrated circuit to a top of the main printed circuit board over the open section so that at least a portion of the bottom of the integrated circuit is exposed over the open section; and
inserting a power block printed circuit board into the open section of the main printed circuit board from below so that a top of the power block printed circuit board makes electrical contact to the bottom of the integrated circuit.

22. The method of claim 21, further comprising securing the power block printed circuit board to the main printed circuit board using a conductive paste and sintering process, and/or one engaging one or more spring clips.
